(19) United States
(12) Patent Application Publication
(10) Pub. No.: US 2008/0029803 A1
(43) Pub. Date: Feb. 7, 2008

(54) Programmable non-volatile memory cell

(75) Inventors: Klaus Dieter Ufert, Unterschleissheim (DE); Josef Willer, Riemerling (DE); David Abookasis, Irvine, CA (US)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Munchen (DE)

(21) Appl. No.: 11/497,528

(22) Filed: Aug. 2, 2006

(51) Int. Cl. H01L 29/788

(52) U.S. Cl. 257/315

(57) ABSTRACT

The present invention relates to a reprogrammable non-volatile memory cell which comprises a selection transistor and a data storage element. The invention further relates to a method of fabricating such a memory cell, as well as to a memory cell array comprising a number of such memory cells.

### TECHNICAL FIELD OF THE INVENTION

The present invention relates to a reprogrammable non-volatile memory cell, the memory characteristic of which is based on the generation of a dielectric breakdown of a dielectric layer. Further, the invention relates to a method of fabricating such a memory cell, as well as to a memory cell array comprising a number of such memory cells.

### BACKGROUND OF THE INVENTION

In various data processing systems and devices, so-called non-volatile memories are employed. These memories have memory cells, in which stored information is reliably maintained even without external energy supply. Thereby, in contrast to volatile data memories, no loss of the memory content occurs immediately after turning off the supply voltage of the memory.

One known type of non-volatile memory is the so-called PROM memory (Programmable Read Only Memory), whose memory cells which are configured e.g. as fuses usually can be programmed only once. Furthermore reprogrammable non-volatile memories are known, e.g. the EPROM memory (Erasable Programmable Read Only Memory) and the EEPROM memory (Electrically Erasable Programmable Read Only Memory). In these memory types, the memory cells each comprise a MOSFET transistor (Metal Oxide Semiconductor Field Effect Transistor) having an isolated auxiliary electrode referred to as “floating gate”.

At this, a programming operation of the memory is based on the application of an electrical charge to the auxiliary electrodes of the transistors, thereby setting the drive voltage of the associated transistors and thus the memory content thereof. For reading the memory, the drive voltage of the transistors is sensed respectively.

Erasing a memory content is effected by discharging the auxiliary electrodes of the transistors. To this end, UV light is employed in an EPROM memory. In contrast, in an EEPROM memory, the erasing operation is performed in an electrical manner. Subsequently, the memory can be reprogrammed by recharging the auxiliary electrodes of the transistors.

Moreover, reprogrammable non-volatile memories are known, which are based on exploitation of further electrical characteristics and phenomena. The U.S. Pat. No. 6,956,258 B2 discloses a memory, in which a dielectric breakdown of a dielectric layer is induced for setting binary information. In this memory, the memory cells disposed on a substrate are each configured as a series connection of a MOS selection transistor and a data storage element, also referred to as MOS half-transistor, by means of a common n+-contact diffused into a p doped region of the substrate. At this, the selection transistor and the data storage element of a memory cell are disposed substantially laterally side by side in a plane.

Herein, the data storage element comprises the dielectric layer provided for programming, which is an oxide layer. For programming a memory cell, a sufficient potential difference can be generated over the dielectric layer of the respective data storage element with the aid of the corresponding selection transistor, thus generating a dielectric breakdown of the dielectric layer, upon which the level of a leakage current through the memory cell is set. In a reading operation, the leakage current level of the individual memory cells is sensed.

This procedure of generating a potential difference over the dielectric layer of the data storage element of a memory cell can be repeated multiple times for the purpose of reprogramming the respective memory cell, thereby gradually increasing the intensity and the degree of the breakdown of the dielectric layer, respectively, upon which the resistance of the data storage element of the memory cell is decreased. In corresponding manner, the leakage current level of the respective memory cell, which is again sensed for reading the memory cell, increases with the degree of dielectric breakdown.

An important aspect of CMOS (Complementary Metal Oxide Semiconductor) memory technology is the required space of a single memory cell of a memory. In the above described memory, a memory cell occupies a relatively large area due to the planar arrangement of the selection transistor and the data storage element, wherein the dielectric layer of the data storage element and a gate oxide layer of the selection transistor are disposed in a plane on the surface of the substrate. Accordingly, a memory cell array comprising these memory cells has a relatively great lateral space requirement, whereby the memory only insufficiently meets the demands of the semiconductor industry for a high integration density.

### SUMMARY OF THE INVENTION

The present invention provides an improved reprogrammable non-volatile memory cell, an improved method of fabricating a reprogrammable non-volatile memory cell, and an improved memory cell array comprising such memory cells.

In one embodiment of the present invention, there is a reprogrammable non-volatile memory cell comprising a selection transistor and a data storage element. The selection transistor comprises an isolation layer, a first terminal on the isolation layer, a second terminal below the isolation layer and in a region below the first terminal, and a third terminal below the isolation layer and in a region below the first terminal, the third terminal being separated from the second terminal. The data storage element comprises a fourth terminal, a fifth terminal and a reprogrammable dielectric layer. The fourth terminal and the fifth terminal of the data storage element are separated from each other by the reprogrammable dielectric layer. The third terminal of the selection transistor is electrically connected to the fourth terminal of the data storage element. The reprogrammable dielectric layer of the data storage element is disposed substantially orthogonally to the isolation layer of the selection transistor.

In another embodiment of the present invention, there is a reprogrammable non-volatile memory cell comprising a selection transistor and a data storage element. The selection transistor comprises an isolation layer, a first terminal on the isolation layer, a second terminal below the isolation layer and in a region below the first terminal, and a third terminal below the isolation layer and in a region below the first terminal, the third terminal being separated from the second terminal. The data storage element comprises a fourth terminal, a fifth terminal and a reprogrammable dielectric layer. The fourth terminal and the fifth terminal of the data storage element are separated from each other by the reprogrammable dielectric layer. The third terminal of the selection transistor is electrically connected to the fourth terminal of the data storage element. The fourth terminal of the data storage element comprises a contact area substantially orthogonal to the isolation layer of the selection transistor, wherein the reprogrammable dielectric layer of the data storage element is on the contact area. A sidewall of a trench comprises the contact area of the fourth terminal of the data storage element, the sidewall of the trench being substantially orthogonal to the isolation layer.

In still another embodiment of the present invention, there is a method of fabricating a reprogrammable non-volatile memory cell, which comprises providing a substrate and forming an initial structure, the initial structure comprising an isolation layer on a surface of the substrate, a first terminal on the isolation layer, a second terminal below the isolation layer and in a region below the first terminal, a third terminal below the isolation layer and in a region below the first terminal, the third terminal being separated from the second terminal, and a contact region in a region below the first terminal, the contact region being separated from the second terminal and electrically connected to the third terminal. A fourth terminal is formed by forming a contact area substantially orthogonal to the isolation layer at the contact region. A dielectric layer is formed on the contact area of the fourth terminal, and a fifth terminal is formed at the dielectric layer, wherein the fifth terminal is separated from the fourth terminal by the dielectric layer.

In yet another embodiment of the present invention, there is a method of fabricating a reprogrammable non-volatile memory cell, which comprises providing a substrate and forming an initial structure, the initial structure comprising an isolation layer on a surface of the substrate, a first terminal on the isolation layer, a second terminal below the isolation layer and in a region below the first terminal, a third terminal below the isolation layer and in a region below the first terminal, the third terminal being separated from the second terminal, and a contact region in a region below the first terminal, the contact region being separated from the second terminal and electrically connected to the third terminal. A fourth terminal with a contact area substantially orthogonal to the isolation layer is formed by forming a trench in the substrate in the area of the contact region with a sidewall substantially orthogonal to the isolation layer, the sidewall of the trench comprising the contact area of the fourth terminal. A dielectric layer is formed on the contact area of the fourth terminal, and a fifth terminal is formed at the dielectric layer, wherein the fifth terminal is separated from the fourth terminal by the dielectric layer.

In another embodiment of the present invention, there is a memory cell array which comprises a number of word lines, a number of bit lines and a number of reprogrammable non-volatile memory cells disposed in corresponding intersections of the word lines and the bit lines. Each of the memory cells comprise a selection transistor and a data storage element. The selection transistor of a memory cell comprises an isolation layer, a first terminal on the isolation layer, a second terminal below the isolation layer and in a region below the first terminal, and a third terminal below the isolation layer and in a region below the first terminal, the third terminal being separated from the second terminal. The data storage element of a memory cell comprises a fourth terminal, a fifth terminal and a reprogrammable dielectric layer. The fourth terminal and the fifth terminal of the data storage element of a memory cell are separated from each other by the corresponding reprogrammable dielectric layer. The third terminal of the selection transistor of a memory cell is electrically connected to the fourth terminal of the data storage element of the corresponding memory cell. The reprogrammable dielectric layer of the data storage element of a memory cell is disposed substantially orthogonally to the isolation layer of the selection transistor of the corresponding memory cell. A word line is connected to the first terminal of the selection transistor of a memory cell. A bit line is connected to the fifth terminal of the data storage element of a memory cell.

In yet another embodiment of the present invention, there is a memory cell array which comprises a number of word lines, a number of bit lines and a number of reprogrammable non-volatile memory cells disposed in corresponding intersections of the word lines and the bit lines. Each of the memory cells comprise a selection transistor and a data storage element. The selection transistor of a memory cell comprises an isolation layer, a first terminal on the isolation layer, a second terminal below the isolation layer and in a region below the first terminal, and a third terminal below the isolation layer and in a region below the first terminal, the third terminal being separated from the second terminal. The data storage element of a memory cell comprises a fourth terminal, a fifth terminal and a reprogrammable dielectric layer. The fourth terminal and the fifth terminal of the data storage element of a memory cell are separated from each other by the corresponding reprogrammable dielectric layer. The third terminal of the selection transistor of a memory cell is electrically connected to the fourth terminal of the data storage element of the corresponding memory cell. The fourth terminal of the data storage element of a memory cell comprises a contact area substantially orthogonal to the isolation layer of the selection transistor of the corresponding memory cell. The reprogrammable dielectric layer of the data storage element of a memory cell is on the corresponding contact area. A sidewall of a trench comprises the contact area of the fourth terminal of the data storage element of a memory cell, the sidewall of the trench being substantially orthogonal to the isolation layer of the corresponding memory cell. A word line is connected to the first terminal of the selection transistor of a memory cell. A bit line is connected to the fifth terminal of the data storage element of a memory cell.

### BRIEF DESCRIPTION OF THE DRAWINGS

These and other features of the present invention will become clear from the following description taken in conjunction with the accompanying drawings. It is to be noted, however, that the accompanying drawings illustrate only typical embodiments of the present invention and are, therefore not to be considered limiting of the scope of the invention. The present invention may admit other equally effective embodiments.

FIG. 1 illustrates a top view of a substrate after fabricating isolation strips and word lines for a memory cell array comprising memory cells according to a preferred embodiment of the invention.

FIG. 2 illustrates a side sectional view of the substrate taken along line A-A of FIG. 1.

FIGS. 3 to 8 illustrate side sectional views of the substrate corresponding to line C-C of FIG. 1, representing further method steps of the fabrication of memory cells according to the invention.

FIG. 9 illustrates a schematic side sectional view of the substrate corresponding to FIGS. 3 to 8, including the finished memory cells of the memory cell array according to the invention.

FIG. 10 illustrates a top view of the substrate including the finished memory cell array.

FIG. 11 illustrates a side sectional view of the substrate taken along line B-B of FIG. 10.

FIG. 12 illustrates a schematic side sectional view of the substrate taken along line A-A of FIG. 10.

### DETAILED DESCRIPTION OF THE INVENTION

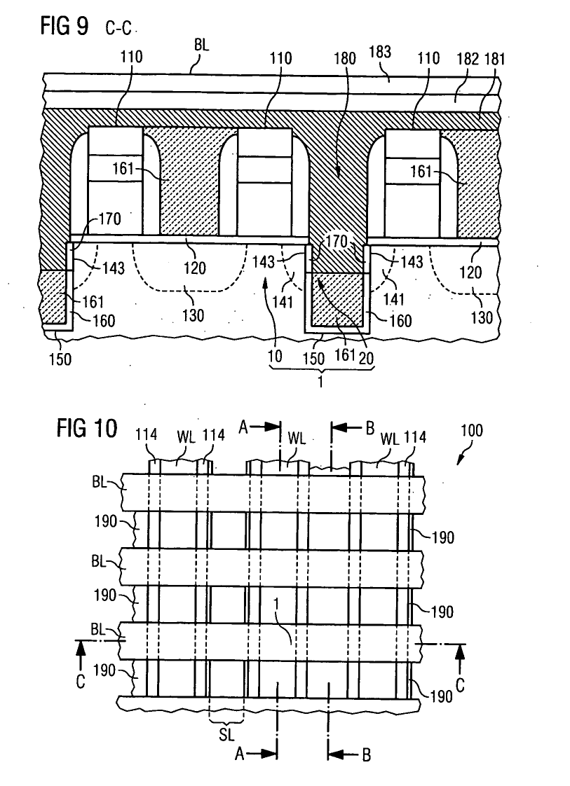

The figures illustrate, in various views, the fabrication of a memory cell array for a memory or memory chip, respectively, with memory cells 1 according to a preferred embodiment of the invention. A memory cell 1 fabricated in this manner on a semiconductor substrate 100 comprises a selection transistor 10 and a data storage element 20 having a reprogrammable dielectric layer 170 (cf. FIG. 9), wherein a dielectric breakdown can be generated or the degree of a dielectric breakdown can be gradually increased, respectively, for programming or reprogramming, respectively. Therein, the magnitude of the dielectric breakdown constitutes the electrical resistance and thus the level of a leakage current of the memory cell 1, which is sensed for reading out the memory cell 1.

In the invention, there is an orthogonal or substantially orthogonal arrangement between the reprogrammable dielectric layer 170 of the data storage element 20 and a gate oxide layer 120 of the selection transistor 10 formed on a surface of the substrate 100. Therein, the dielectric layer 170 of the data storage element 20 and the gate oxide layer 120 of the selection transistor 10 can also form an angle, which differs from a right angle by an angle in the range of e.g. 20 degrees at most, which angle is due to the method of fabrication. The configuration according to the invention provides a small distance between the selection transistor 10 and the data storage element 20, whereby the memory cell 1 according to the invention has a small lateral space on the surface of the substrate 100. In the following, first, a fabrication method is dealt with, which advantageously can be performed particularly with the aid of standard CMOS process steps.

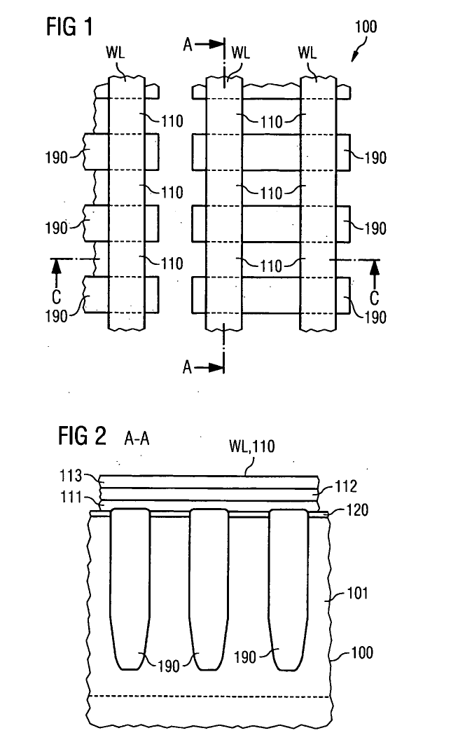

At the beginning of the fabrication method, in a substrate 100, which has a e.g. p-doped region 101 extending from the surface, isolation strips 190 are formed (cf. the schematic top view of FIG. 1 as well as the schematic side sectional view of FIG. 2 taken along line A-A of FIG. 1). The isolation strips 190, which are also referred to as STI strips (Shallow Trench Isolation) and which comprise e.g. an oxide material, define the active regions isolated from each other for the later memory cells 1.

Subsequently, an oxide layer 120 is formed on the substrate 100, which serves as a gate oxide layer 120 for selection transistors 10 of later memory cells 1. Therein, the oxide layer 120 is disposed on the surface of the substrate 100 between the isolation strips 190, as becomes apparent from the side sectional view of FIG. 2, and has a thickness e.g. in a range greater than 5 nm.

Subsequently, word lines WL are formed on the surface of the substrate 100, which also serve as gates 110 for selection transistors 10 of the memory cells 1 in the active regions. To this end, preferably, a non-doped or an n+-doped polysilicon layer 111, a metal layer 112 e.g. comprising WSi and at least one hard mask layer 113 e.g. comprising a nitride, are applied onto the surface of the substrate 100 in a large area. This stack of layers is subsequently structured with the aid of a lithographic method and one or several etching methods such as e.g. reactive ion etching for forming the word lines WL and gates 110, respectively. The word lines WL and gates 110, respectively, fabricated in this manner are depicted in the schematic top view of FIG. 1 as well as in the schematic side sectional view of FIG. 2.

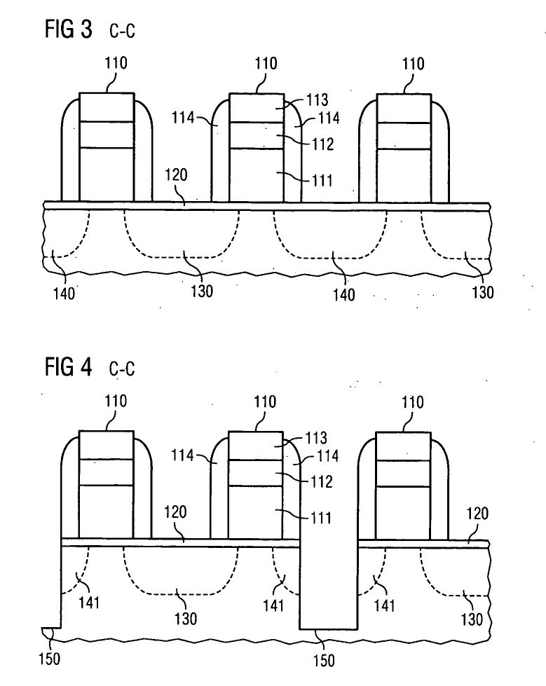

The following FIGS. 3 to 9 show further method steps in fabricating memory cells 1 according to the invention in a schematic side sectional view, corresponding to line C-C of FIG. 1 and FIG. 10, respectively. As becomes apparent from FIG. 3, first, liners or spacers 114 laterally adjoining the word lines WL or the gates 110, respectively, are formed. Subsequently, within the scope of a doping method applying corresponding implant materials, n+-doped regions 130, 140 are produced in self-adjusting manner below the oxide layer 120 between the gates 110 or in a region below the gates 110, respectively. Therein, the doping method can include an annealing method step. The n+-doped regions 130, 140 constitute sources/drains for selection transistors 10 and terminals for data storage elements 20 of later memory cells 1 at a later stage in the fabrication process. A region 130, which is disposed between the isolation strips 190 separated from each other in the top view, is further connected to a buried source line SL formed by diffusion operations (cf. FIGS. 9 and 10).

Starting from the structure depicted in FIG. 3, as illustrated in FIG. 4, trenches 150 are formed in every second gap between the gates 110 in the region of the n+-doped regions 140, the trenches 150 having sidewalls oriented orthogonally or substantially orthogonally to the oxide layer 120, respectively, on which dielectric layers 170 of data storage elements 20 are formed in the further course of the fabrication method. The formation of trenches 150 includes e.g. depositing one or several hard mask layers (not illustrated), subsequently employing a lithographic method and one or several etching methods such as the selective reactive ion etching, as well as removing the hard mask layer(s).

As becomes apparent from FIG. 4, by a trench 150, an n+-doped region 140 is divided in two partial regions 141 each associated with later memory cells 1 disposed side by side, and separated from each other by the trench 150. The depth of a trench 150, which is preferably in a range of 100 nm to 200 nm, therein exceeds a maximum depth of an n+-doped region 140 and thus a maximum depth of a partial region 141. The maximum depth is each understood as the maximum extent of the respective regions 140, 141 extending downwards from the surface of the substrate 100. The partial regions 141 serve both as drains for selection transistors 10 and terminals for data storage elements 20 of later memory cells 1.

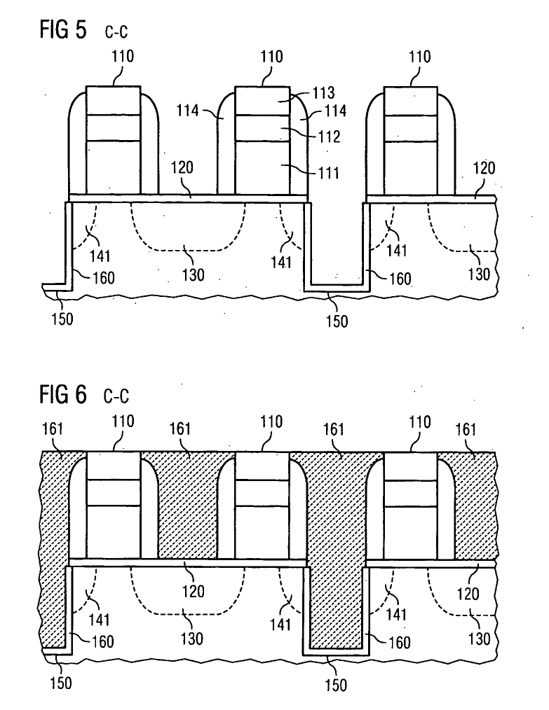

Subsequently, a sacrificial oxide layer 160 is formed on sidewalls and on a bottom of each trench 150, as illustrated in FIG. 5. Subsequently, each trench 150 as well as corresponding regions between the gates 110 are filled with an oxide material 161, as becomes apparent from FIG. 6. For this, the oxide material 161 is e.g. applied onto the surface of the substrate 100 in a large area, and subsequently ablated with the aid of a CMP process (chemical-mechanical polishing) to an upper edge of the gates 110 to obtain the structure illustrated in FIG. 6.

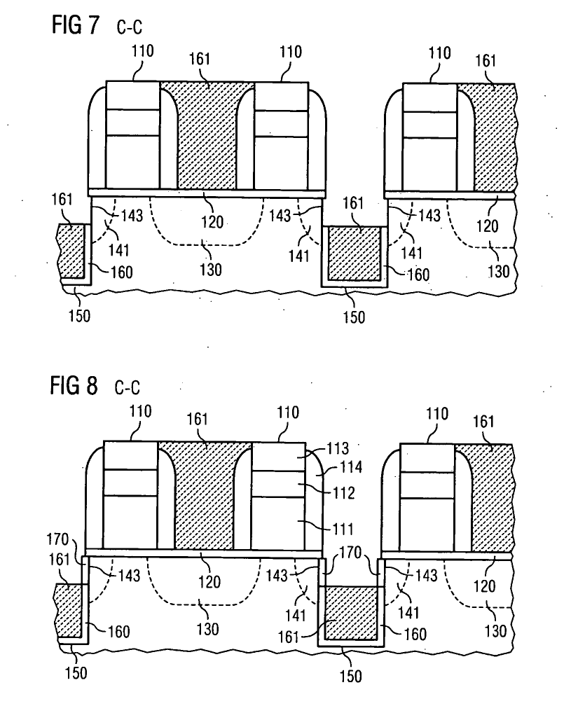

Subsequently, the oxide material 161 between the gates 110 is removed completely in the region of the trenches 150, and both the oxide material 161 and the sacrificial oxide 160 are partially removed in the trenches 150 such that the trenches 150 continue to be partially filled with the oxide 161 and the sacrificial oxide 160, as illustrated in FIG. 7. For removing the oxide material 161 and the sacrificial oxide 160, corresponding lithographic and etching methods are employed. Therein, the oxide 161 as well as the sacrificial oxide 160 disposed between sidewalls, a bottom of a trench 150 and the oxide 161 fill a trench 150 to a level above the maximum depth of a partial region 141 present at the border of the respective trench 150.

In this manner, exposed contact areas 143 above the oxide 161 and the sacrificial oxide 160 are provided for the partial regions or terminals 141, respectively. At this, the sidewalls of a trench 150 arranged orthogonally to the oxide layer 120 comprise the contact areas 143. Dielectric oxide layers 170 for data storage elements 20 of memory cells 1 are formed on the contact areas 143, as illustrated in FIG. 8. The oxide layers 170, referred to as dielectric layers 170 in the following, are utilized for (re)programming the later memory cells 1. Since the dielectric layers 170 are merely formed above a maximum depth extent of the partial regions 141 on the contact areas 143, a reliable operation of the memory cells 1 is possible. The dielectric layers 170, which are oriented orthogonally to the gate oxide layer 120 corresponding to the sidewalls of the trenches 150 or the contact areas 143 of the terminals 141, respectively, preferably have a thickness in a range of 2 nm to 3 nm.

As a final method step in fabricating the memory cells 1 according to the invention, terminals 180 contacting the dielectric layers 170 and bit lines BL connected to the terminals 180 are formed on the surface of the substrate 100, as illustrated in FIG. 9. To this end, preferably, a non-doped or an n+-doped polysilicon layer 181, a metal layer 182 comprising e.g. WSi and at least one hard mask layer 183 comprising e.g. a nitride, are applied onto the substrate 100 in a large area, wherein the polysilicon layer 181 fills in the exposed spaces between the gates 110 and the exposed regions of the trenches 150. Subsequently, the stack of layers is structured with the aid of a lithographic method and one or several etching methods such as e.g. reactive ion etching for forming the bit lines BL and terminals 180, respectively.

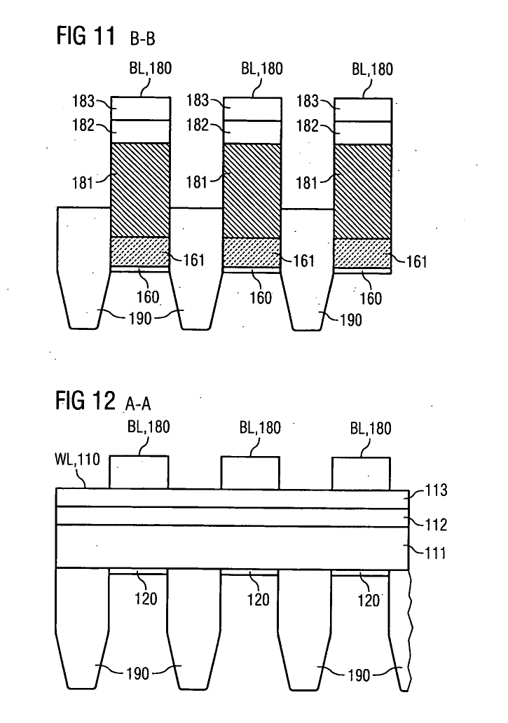

The memory cell array fabricated in this manner with a number of word lines WL, a number of bit lines BL, a number of memory cells 1 disposed in corresponding intersections of the word lines WL and bit lines BL, as well as a number of buried source lines SL, is illustrated in the top view of FIG. 10. Therein, FIG. 9 illustrates the side sectional view taken along line C-C of FIG. 10. For better illustration, the FIGS. 11 and 12 show further sectional views of the memory cell array taken along line B-B (FIG. 11) as well as along line A-A (FIG. 12) of FIG. 10.

By way of the side sectional view of FIG. 9, the configuration of an individual memory cell 1 becomes apparent. The memory cell 1 comprises a selection transistor 10 (presently configures as NMOS transistor), the selection transistor 10 including a gate oxide layer 120, a gate 110 connected to a word line WL or formed by the word line WL, respectively, on the gate oxide layer 120, an n+-doped region 130 serving as a source, as well as a terminal 141 serving as a drain, the region 130 and the terminal 141 being below the gate oxide layer 120 in a region below the gate 110. The region 130 also forms a buried source line SL proceeding between isolation strips 190, or is connected to a source line SL, respectively (cf. FIG. 10).

The memory cell 1 further comprises a data storage element 20 connected in series with the selection transistor 10, the data storage element 20 including a terminal 141, a reprogrammable dielectric layer 170 arranged rectangularly to the gate oxide 120 of the selection transistor 10, as well as a terminal 180 connected to a bit line BL. Therein, the terminal 141 is used as a common terminal by both the selection transistor 10 and the data storage element 20 of the memory cell 1.

Due to the orthogonal arrangement of the dielectric layer 170 of the data storage element 20 and the gate oxide layer 120 of the selection transistor 10, the selection transistor 10 and the data storage element 20 can be disposed in a relatively small distance to each other. In this manner, the memory cell 1 according to the invention formed on the substrate 100 has a small lateral extent on the surface of the substrate 100. For example, it is possible to realize the memory cell 1 with a lateral dimension in a range below 50 nm. A memory or memory chip, respectively, comprising a memory cell array including memory cells 1 according to the invention thus is characterized by a high integration density. Additionally, the common terminal 141 utilized by the selection transistor 10 and the data storage element 20 also lowers the space requirement of the memory cell 1.

A space saving geometry of memory cells 1 disposed in the memory cell array is further achieved by at least one pair of two memory cells 1 disposed side by side as well as associated with a bit line BL having a common terminal 180. In corresponding manner, a small lateral extent is also achieved by at least one pair of two memory cells 1 disposed side by side and associated with a bit line BL having a common n+-doped region or source 130, respectively.

For programming a memory cell 1 according to the invention, a dielectric breakdown of the dielectric layer 170 of the data storage element 20 of the memory cell 1 is generated. In this manner, the dielectric layer 170 no longer behaves like an isolator, but like a finite electrical resistance. Therein, the magnitude of the dielectric breakdown constitutes the level of a leakage current through the memory cell 1, which is measured in a reading operation of the memory cell. For forming a breakdown of the dielectric layer 170, a sufficient potential difference over the data storage element 20 or over the dielectric layer 170 thereof, respectively, is applied with the aid of the two terminals 141, 180 of the data storage element 20.

To this end, in case of the selection transistor 10 formed as a NMOS transistor, e.g. a positive voltage different from 0V is applied to the gate 110 of the selection transistor 10 through the corresponding word line WL, as well as a voltage of 0v is applied to the source 130 of the selection transistor 10 through the corresponding source line SL, thereby turning on the selection transistor 10. In this manner, the drain 141 of the selection transistor 10 is also brought to a potential of 0V. Therein, the indicated potentials refer to the substrate 100 as the ground potential.

By applying a sufficiently high positive potential, higher with respect to the potential applied to the gate 110 of the selection transistor 10, to the terminal 180 of the data storage element 20 through the corresponding bit line BL, the breakdown of the dielectric layer 170 for programming the memory cell 1 can be induced. The resulting conductive path has sufficient electrical resistance to prevent the gate oxide layer 120 of the selection transistor 10 from being degraded or breaking down, in this manner preventing damage of the memory cell 1. Damage to the gate oxide layer 120 of the selection transistor 10 is further avoided by the thickness of the gate oxide layer 120 of the selection transistor 10 exceeding the thickness of the dielectric layer 170 of the data storage element 20.

For reading the memory cell 1, in case of the selection transistor 10 configured as a NMOS transistor, again, e.g. a positive potential different from 0V is applied to the gate 110 of the selection transistor 10 through the corresponding word line WL, and a potential of 0V is applied to the source 130 of the selection transistor 10 through the corresponding source line SL. In this manner, the selection transistor 10 is turned on and the drain 141 is also brought to a potential of 0 V. Furthermore, a positive potential, lower with respect to the potential applied to the gate 110 of the selection transistor 10, is applied to the terminal 180 of the data storage element 20 through the corresponding bit line BL. If the memory cell 1 is programmed, i.e. the dielectric layer 170 of the data storage element 20 is broken down, a leakage current flows through the memory cell 1, which can be measured on the bit line BL with the aid of an appropriate measuring device. If the memory cell 1 is not programmed, no or only a negligible leakage current flows, respectively. For reading out the memory content of a memory cell array comprising memory cells 1, a threshold value of the leakage current level of the memory cells 1 is set. In this manner, the logical states stored in the memory cells 1 (no or negligible leakage current below the threshold value, respectively/leakage current above the threshold value) can be distinguished from each other.

For the purpose of reprogramming a memory cell 1, the above described programming step can be repeated multiple times. For this, an ever increasing potential difference is established across the dielectric layer 170 of the data storage element 20 and/or the potential difference across the dielectric layer 170 is generated for an ever increasing duration of the programming step. In this manner, the degree of the dielectric breakdown of the dielectric layer 170 is incrementally increased, and thus the resistance thereof is gradually decreased. In corresponding manner, thereby, the leakage current level of the memory cell 1 is gradually increased.

For “erasing” the memory content of an already programmed memory cell, the threshold value of the leakage current level set for reading is increased. In this manner, a (re)programmed memory cell 1 having an increased leakage current level can be reset into a “non-programmed” state again. After each reprogramming of memory cells 1, therefore, usually the threshold value of the leakage current level measured on the memory cells 1 is increased in order to distinguish the logical states stored in the memory cells 1 (leakage current level below the threshold value/leakage current level above the threshold value).

While the present invention has been described in terms of specific embodiments, it is evident in view of the foregoing description that various variations and modifications may be carried out without departing from the scope of the invention.

As an example, it is possible to realize a gate 110 of a selection transistor 10 as well as a terminal 180 of a data storage element 20 of a memory cell 1 with a configuration other than the illustrated layer staples as well as with other materials.

Furthermore, instead of the terminal 141 of the selection transistor and the terminal 141 of the data storage element 20 being the same terminal, two terminals electrically connected to each other can be formed.

Further, instead of forming n+-doped contact regions 130, 140 or terminals 141, respectively, in a p-doped region 101 of a substrate 100 extending from the surface, p+-doped contact regions in an n-doped region of a substrate extending from the surface, and thus selection transistors configured as PMOS transistors can be formed in corresponding manner.

Also, the procedure indicated above for (re)programming and for reading out memory cells 1 is only of exemplary nature. Particularly, programming or (re)programming of a memory cell 1, respectively, is based on generating or enhancing a breakdown of a dielectric layer 170 of a data storage element 20, in this manner constituting a leakage current level of the corresponding memory cell 1. This can be achieved by establishing a sufficient potential difference over the dielectric layer 170 with the aid of the corresponding selection transistor 10.

What is claimed is:

1. A reprogrammable non-volatile memory cell, comprising:
a selection transistor, comprising:
an isolation layer,
a first terminal on the isolation layer,
a second terminal below the isolation layer and in a region below the first terminal, and
a third terminal below the isolation layer and in a region below the first terminal, the third terminal being separated from the second terminal; and
a data storage element, comprising:
a fourth terminal,
a fifth terminal, and
a reprogrammable dielectric layer, wherein
the fourth terminal and the fifth terminal of the data storage element are separated from each other by the reprogrammable dielectric layer,
the third terminal of the selection transistor is electrically connected to the fourth terminal of the data storage element, and
the reprogrammable dielectric layer of the data storage element is disposed substantially orthogonally to the isolation layer of the selection transistor.

2. The memory cell according to claim 1, wherein the third terminal of the selection transistor and the fourth terminal of the data storage element are the same terminal.

3. The memory cell according to claim 1, wherein the fourth terminal of the data storage element comprises a contact area substantially orthogonal to the isolation layer of the selection transistor.

4. The memory cell according to claim 3, wherein the reprogrammable dielectric layer of the data storage element is on the contact area of the fourth terminal.

5. The memory cell according to claim 1, wherein the reprogrammable dielectric layer of the data storage element has a thickness in a range of 2nm to 3nm.

6. The memory cell according to claim 1, wherein the reprogrammable dielectric layer of the data storage element comprises an oxide layer.

7. A reprogrammable non-volatile memory cell comprising:
a selection transistor, comprising:
an isolation layer,
a first terminal on the isolation layer,
a second terminal below the isolation layer and in a region below the first terminal, and
a third terminal below the isolation layer and in a region below the first terminal, the third terminal being separated from the second terminal; and
a data storage element, comprising:
a fourth terminal,
a fifth terminal, and
a reprogrammable dielectric layer, wherein
the fourth terminal and the fifth terminal of the data storage element are separated from each other by the reprogrammable dielectric layer,
the third terminal of the selection transistor is electrically connected to the fourth terminal of the data storage element,
the fourth terminal of the data storage element comprises a contact area substantially orthogonal to the isolation layer of the selection transistor,
the reprogrammable dielectric layer of the data storage element is on the contact area, and
a sidewall of a trench comprises the contact area of the fourth terminal of the data storage element, the sidewall of the trench being substantially orthogonal to the isolation layer.

8. The memory cell according to claim 7, wherein a depth of the trench exceeds a maximum depth of the fourth terminal.

9. The memory cell according to claim 8, wherein the trench is filled with an oxide layer to a level above the maximum depth of the fourth terminal, and the reprogrammable dielectric layer of the data storage element is disposed above the oxide layer.

10. The memory cell according to claim 9, wherein an intermediate oxide layer fills the trench to the level above the maximum depth of the fourth terminal and is disposed between sidewalls, a bottom of the trench and the oxide layer.

11. The memory cell according to claim 7, wherein the trench has a depth in a range of 100 nm to 200 nm.

12. The memory cell according to claim 7, wherein the third terminal of the selection transistor and the fourth terminal of the data storage element are the same terminal.

13. A method of fabricating a reprogrammable non-volatile memory cell, comprising:
providing a substrate;
is forming an initial structure, comprising:
an isolation layer on a surface of the substrate,
a first terminal on the isolation layer,
a second terminal below the isolation layer and in a region below the first terminal,
a third terminal below the isolation layer and in a region below the first terminal, the third terminal being separated from the second terminal, and
a contact region in a region below the first terminal, the contact region being separated from the second terminal and electrically connected to the third terminal;
forming a fourth terminal by forming a contact area substantially orthogonal to the isolation layer at the contact region;
forming a dielectric layer on the contact area of the fourth terminal; and
forming a fifth terminal at the dielectric layer, wherein the fifth terminal is separated from the fourth terminal by the dielectric layer.

14. The method according to claim 13, wherein forming the initial structure comprises:
forming an isolation layer on a surface of the substrate,
forming a first terminal on the isolation layer, and
forming a second terminal, a third terminal and a contact region below the isolation layer and in a region below the first terminal, the third terminal and the contact region being separated from the second terminal.

15. The method according to claim 13, wherein the third terminal and the fourth terminal are formed as the same terminal.

16. The method according to claim 13, wherein the dielectric layer comprises an oxide layer formed on the contact area of the fourth terminal.

17. The method according to claim 13, wherein the second terminal, the third terminal, the fourth terminal and the contact region, respectively, are formed by doping the substrate.

18. A method of fabricating a reprogrammable non-volatile memory cell, comprising:
providing a substrate;
forming an initial structure, comprising:
an isolation layer on a surface of the substrate,
a first terminal on the isolation layer,
a second terminal below the isolation layer and in a region below the first terminal,
a third terminal below the isolation layer and in a region below the first terminal, the third terminal being separated from the second terminal, and
a contact region in a region below the first terminal, the contact region being separated from the second terminal and electrically connected to the third terminal;
forming a fourth terminal with a contact area substantially orthogonal to the isolation layer by forming a trench in the substrate in the area of the contact region with a sidewall substantially orthogonal to the isolation layer, the sidewall of the trench comprising the contact area of the fourth terminal;
forming a dielectric layer on the contact area of the fourth terminal; and
forming a fifth terminal at the dielectric layer, wherein the fifth terminal is separated from the fourth terminal by the dielectric layer.

19. The method according to claim 18, wherein a depth of the trench exceeds a maximum depth of the contact region.

20. The method according to claim 18, after forming the trench, comprising:
forming an oxide layer in the trench, wherein the oxide layer fills the trench to a level above a maximum depth of the fourth terminal, and
forming the dielectric layer above the oxide layer on the contact area of the fourth terminal.

21. The method according to claim 20, wherein forming the oxide layer in the trench comprises:
forming an intermediate oxide layer on sidewalls and on a bottom of the trench,
filling the trench with an oxide material for the oxide layer, and
removing the oxide material and the intermediate oxide layer to the level above the maximum depth of the fourth terminal, thereby forming the oxide layer in the trench.

22. The Method according to claim 18, wherein the third terminal and the fourth terminal are formed as the same terminal.

23. A memory cell array comprising a number of word lines, a number of bit lines and a number of reprogrammable non-volatile memory cells disposed in corresponding intersections of the word lines and the bit lines, each of the memory cells comprising:
a selection transistor, comprising:
an isolation layer,
a first terminal on the isolation layer,
a second terminal below the isolation layer and in a region below the first terminal, and
a third terminal below the isolation layer and in a region below the first terminal, the third terminal being separated from the second terminal; and
a data storage element, comprising:
a fourth terminal,
a fifth terminal,
a reprogrammable dielectric layer, wherein
the fourth terminal and the fifth terminal of the data storage element of a memory cell are separated from each other by the corresponding reprogrammable dielectric layer,
the third terminal of the selection transistor of a memory cell is electrically connected to the fourth terminal of the data storage element of the corresponding memory cell,
the reprogrammable dielectric layer of the data storage element of a memory cell is disposed substantially orthogonally to the isolation layer of the selection transistor of the corresponding memory cell,
a word line is connected to the first terminal of the selection transistor of a memory cell, and
a bit line is connected to the fifth terminal of the data storage element of a memory cell.

24. The memory cell array according to claim 23, wherein at least one pair of two memory cells disposed side by side have a common fifth terminal.

25. The memory cell array according to claim 23, wherein at least one pair of two memory cells disposed side by side have a common second terminal.

26. The memory cell array according to claim 23, comprising a number of source lines, wherein a source line is connected to the second terminal of the selection transistor of a memory cell.

27. A memory cell array comprising a number of word lines, a number of bit lines and a number of reprogrammable non-volatile memory cells disposed in corresponding intersections of the word lines and the bit lines, each of the memory cells comprising:
a selection transistor, comprising:
an isolation layer,
a first terminal on the isolation layer,
a second terminal below the isolation layer and in a region below the first terminal,
a third terminal below the isolation layer and in a region below the first terminal, the third terminal being separated from the second terminal; and
a data storage element, comprising:
a fourth terminal,
a fifth terminal,
a reprogrammable dielectric layer, wherein
the fourth terminal and the fifth terminal of the data storage element of a memory cell are separated from each other by the corresponding reprogrammable dielectric layer,
the third terminal of the selection transistor of a memory cell is electrically connected to the fourth terminal of the data storage element of the corresponding memory cell,
the fourth terminal of the data storage element of a memory cell comprises a contact area substantially orthogonal to the isolation layer of the selection transistor of the corresponding memory cell,
the reprogrammable dielectric layer of the data storage element of a memory cell is on the corresponding contact area,
a sidewall of a trench comprises the contact area of the fourth terminal of the data storage element of a memory cell, the sidewall of the trench being substantially orthogonal to the isolation layer of the corresponding memory cell,
a word line is connected to the first terminal of the selection transistor of a memory cell, and
a bit line is connected to the fifth terminal of the data storage element of a memory cell.
